(19) United States
(12) Patent Application Publication
(10) Pub. No.: US 2026/0216764 A1
(43) Pub. Date: Jul. 30, 2026

(54) METHOD OF CLEANING POT-SHAPED HOLLOW BODIES, IN PARTICULAR TRANSPORT CONTAINERS FOR SEMICONDUCTOR WAFERS OR FOR LITHOGRAPHY MASKS WITH A CORRESPONDING DEVICE

(71) Applicant: GSEC GERMAN SEMICONDUCTOR EQUIPMENT COMPANY GMBH, Radolfzell am Bodensee (DE)

(72) Inventor: Lutz Rebstock, Gaienhofen (DE)

(21) Appl. No.: 19/145,511

(22) PCT Filed: Jan. 4, 2024
(86) PCT No.: PCT/EP2024/050144

§ 371 Date: Jul. 3, 2025

(30) Foreign Application Priority Data
Jan. 13, 2023 (DE) 10 2023 100 730.0

(51) Int. Cl. B08B 9/093

(52) U.S. Cl. CPC B08B 9/093

(57) ABSTRACT

Methods for cleaning pot-shaped hollow bodies, in particular transport containers for semiconductor wafers or for lithography masks with a corresponding device, the method comprising the following steps: dispensing of a first cleaning fluid for cleaning the inner hollow body surface by the first dispensing unit, draining the first cleaning fluid by the first drainage channel, wherein the first cleaning fluid has a first surface tension, dispensing of a second cleaning fluid for cleaning the inner hollow body surface by the first dispensing unit, wherein the second cleaning fluid is miscible with the first cleaning fluid and the mixture so generated by the first cleaning fluid and the second cleaning fluid has a mixture surface tension that is lower than the first surface tension, and draining the mixture through the first drainage channel or through a further drainage channel.

### BACKGROUND OF THE INVENTION

### Field of the Invention

Embodiments of the present invention relate to methods of cleaning pot-shaped hollow bodies, and in particular, to transport containers for semiconductor wafers or for lithography masks with a corresponding device.

### Description of the Related Art

The manufacture of highly integrated electronic circuits and other sensitive semiconductor components takes place today in factories in which so-called semiconductor wafers run through a large number of processing steps. A large part of these processing steps takes place in clean rooms that are kept free of contaminants, in particular free of particles as well as free of airborne molecular contaminants (AMC), with a high effort. Such a complex processing is necessary since particles and airborne molecular contaminants that come into contact with the semiconductor material of the semiconductor wafers can in particular influence the material properties of the semiconductor wafers such that a total production batch becomes defective and unusable and has to be scrapped.

Since keeping clean is becoming more and more important as the integration density of the semiconductor circuits and the effort to keep clean increase exponentially as the size of the clean rooms increases, the semiconductor wafers are not transported from one processing station to the next in an “open” state. Special transport containers (so-called FOUPs, front opening unified pods) are used instead. They are understood as box-shaped transport containers into which a large number of semiconductor wafers is inserted. The FOUPs are typically closed by a removable cover. Without the cover the FOUPs have a pot-shaped basic shape with a rectangular base surface. When the FOUPs are closed by their covers, the inserted semiconductor wafers can be transported from one clean room to another clean room protected from the environment. When the FOUPs have reached a processing station, they are opened, the semiconductor wafers are removed, and are processed accordingly. After processing has taken place, the semiconductor wafers are transported back into the FOUPs and are then conveyed to the next processing station.

Due to the high production downtimes on contaminations of the semiconductor wafers, it is necessary to clean the FOUPs from time to time. The FOUPs are mainly contaminated by the wear debris of the semiconductor wafers on the introduction into and the removal from the FOUPs and by AMC that originate from preceding processes.

The same applies accordingly to the transport containers for lithography masks and in particular for EUV lithography masks (“extreme ultraviolet radiation”). The EUV lithography masks are used to manufacture very small integrated circuits. The EUV lithography masks, like the semiconductors, also have to be transported, with a similar situation arising. When FOUPs are spoken of in the following, the statements in this respect apply equally to transport containers for lithography masks.

Devices for cleaning FOUPs are known, for example, from U.S. Pat. No. 5,238,503 A, US 2002/0046760 A1, US 2003/0102015 A1, WO 2022/096657 A1, WO 2005/001888 A2 and EP 1 899 084 B1.

With such cleaning devices, the FOUPs are cleaned at least on their inner surface and optionally also on their outer surface. The FOUPs are usually made of plastic, which means that the inner surfaces and outer surfaces in particular, but also the other surfaces, are not microscopically smooth. Instead, they have microscopic elevations and indentations. Microcracks can also form. The cleaning fluids used for cleaning are usually water-based. While correspondingly small particles and/or AMC can accumulate in the depressions and microcracks and detach from there during operation of the FOUP and consequently have the undesirable influence on the material properties of the semiconductor wafers described above, the cleaning fluid used does not reach the microscopic depressions and microcracks, in particular due to the surface tension. Even if the cleaning process is carried out over a long period of time, at least some particles and AMC cannot be removed from the microscopic recesses and microcracks. It is therefore not possible to prevent these particles and AM from having the undesirable influence on the material properties of the semiconductor wafers described above.

### SUMMARY OF THE INVENTION

It is an object of one embodiment of the present invention to propose a method for cleaning pot-shaped hollow bodies, with which it is possible to remedy the above-mentioned disadvantages by simple and inexpensive means. In particular, a method is to be proposed which also enables the removal of particles and AMC which have accumulated in microscopic depressions and microcracks in the surfaces of the FOUP.

An embodiment of the invention relates to a method of cleaning pot-shaped hollow bodies, in particular transport containers for semiconductor wafers or for lithography masks with a corresponding device. The hollow body can include one or more side walls which form an inner hollow body surface, and an opening that is enclosed by the side wall. The corresponding device can include a cleaning device with a first dispensing unit by which a first cleaning fluid and a second cleaning fluid for cleaning the inner hollow body surface can be dispensed. The corresponding device can further include a first drainage channel through which the first cleaning fluid and the second cleaning fluid dispensed by the cleaning device can be drained. The method includes dispensing a first cleaning fluid for cleaning the inner hollow body surface by the first dispensing unit, draining the first cleaning fluid by the first drainage channel, wherein the first cleaning fluid has a first surface tension, dispensing of a second cleaning fluid for cleaning the inner hollow body surface by the first dispensing unit, wherein the second cleaning fluid is miscible with the first cleaning fluid and the mixture so generated by the first cleaning fluid and the second cleaning fluid has a mixture surface tension that is lower than the first surface tension, and draining the mixture through the first drainage channel or through a further drainage channel.

### BRIEF DESCRIPTION OF THE DRAWINGS

The accompanying FIGURES, in which like reference numerals refer to identical or functionally-similar elements throughout the separate views and which are incorporated in and form a part of the specification, further illustrate the embodiments and, together with the detailed description, serve to explain the embodiments disclosed herein. It is to be noted, however, that the appended drawings illustrate only typical embodiments of this invention and are, therefore, not to be considered limiting of its scope, for the invention may admit to other equally effective embodiments. It is also emphasized that the FIGURES are not necessarily to scale and certain features and certain views of the FIGURES can be shown exaggerated in scale or in schematic for clarity and/or conciseness.

FIG. 1 depicts a schematic sectional view of a first embodiment of a device for cleaning pot-shaped hollow bodies, in particular transport containers for semiconductor wafers or for EUV lithography masks.

FIG. 2 depicts a principle sectional view of a second embodiment of a device for cleaning pot-shaped hollow bodies.

### DETAILED DESCRIPTION

The scope of the invention is defined in the appended claims, which for infringement purposes is recognized as including equivalents to the various elements or limitations specified in the claims. Depending on the context, all references to the “invention” may in some cases refer to certain specific embodiments only. In other cases, it will be recognized that references to the “invention” will refer to subject matter recited in one or more, but not necessarily all, of the claims. Each of the inventions will now be described in greater detail below, including specific embodiments, versions and examples, but the inventions are not limited to these embodiments, versions or examples, which are included to enable a person having ordinary skill in the art to make and use the inventions, when the information in this disclosure is combined with publicly available information and technology.

Furthermore, in the following discussion and in the claims, the terms “including” and “comprising” are used in an open-ended fashion, and thus should be interpreted to mean “including, but not limited to.” The phrase “consisting essentially of” means that the described/claimed composition does not include any other components that will materially alter its properties by any more than 5% of that property, and in any case does not include any other component to a level greater than 3 mass %.

Unless otherwise indicated, all numerical values are “about” or “approximately” the indicated value, meaning the values take into account experimental error, machine tolerances and other variations that would be expected by a person having ordinary skill in the art. It should also be understood that the precise numerical values used in the specification and claims constitute specific embodiments. Efforts have been made to ensure the accuracy of the data in the examples. However, it should be understood that any measured data inherently contains a certain level of error due to the limitation of the technique and/or equipment used for making the measurement.

An embodiment of the invention relates to a method of cleaning pot-shaped hollow bodies, in particular transport containers for semiconductor wafers or for lithography masks with a corresponding device, wherein the hollow body comprises one or more side walls which form an inner hollow body surface, and an opening that is enclosed by the side wall, and the device comprises a cleaning device with a first dispensing unit by which a first cleaning fluid and a second cleaning fluid for cleaning the inner hollow body surface can be dispensed, and a first drainage channel through which the first cleaning fluid and the second cleaning fluid dispensed by the cleaning device can be drained, and the method comprises the following steps: dispensing of a first cleaning fluid for cleaning the inner hollow body surface by the first dispensing unit, draining the first cleaning fluid by the first drainage channel, wherein the first cleaning fluid has a first surface tension, dispensing of a second cleaning fluid for cleaning the inner hollow body surface by the first dispensing unit, wherein the second cleaning fluid is miscible with the first cleaning fluid and the mixture so generated by the first cleaning fluid and the second cleaning fluid has a mixture surface tension that is lower than the first surface tension, and draining the mixture through the first drainage channel or through a further drainage channel.

First, the inner hollow body surface is cleaned with the first cleaning fluid, which can remove the majority of all impurities. The first cleaning fluid is then removed from the cleaning device and in particular from the hollow body. However, a certain amount of the first cleaning fluid remains on the inner hollow body surface. Depending on the cleaning fluid used, this portion evaporates relatively quickly, but the impurities contained in this portion remain locally concentrated. This applies in particular to microscopic indentations on the inner hollow body surface. These impurities can detach from the inner hollow body surface over time and exert the detrimental effects described above on the semiconductor wafers transported in the hollow body in question.

According to the invention, it is not necessary to wait until the residues of the first cleaning fluid have evaporated, but a second cleaning fluid is applied to the inner hollow body surface, which can be mixed with the first cleaning fluid. The second cleaning fluid can already be applied to the inner hollow body surface when the first cleaning fluid has not yet been removed.

The second cleaning fluid is selected so that the resulting mixture has a mixture surface tension that is lower than the first surface tension of the first fluid. This mixture is then removed from the hollow body. It has been shown that this mixture can be removed from the hollow body with virtually no residue. It is therefore possible to prevent impurities from remaining locally concentrated on the inner hollow body surface due to evaporation as described above. Overall, the cleaning result is therefore significantly improved compared to cleaning only with the first cleaning fluid, which also reduces the number of production batches of semiconductor wafers that have to be rejected due to contamination originating from the hollow bodies. For design reasons in particular, it is advisable to discharge both the first cleaning fluid and the mixture using the same first drainage channel, but it may also make sense to discharge the mixture using a further drainage channel.

In accordance with a further embodiment the second cleaning fluid is applied to the inner hollow surface body in the vapor state. It has been shown that supplying the second cleaning fluid in a vapor state leads to an improved cleaning result compared to supplying it in a liquid state.

In a further developed embodiment, water is used as the first cleaning fluid and an organic solvent is used as the second cleaning fluid. The term “organic solvents” can be understood to mean carbon-containing chemical substances that are used to dissolve other substances such as paints, varnishes, grease, oil and the like.

Water is cheaply available and easy to handle. The use of an organic solvent has proven to be suitable for achieving a satisfactory cleaning result.

In a further embodiment the organic solvent has a water solubility of at least 1 g/L and a vapor pressure of between 25 Pa and 25000 Pa. Particularly good cleaning results can be achieved in these areas of water solubility and vapor pressure.

In a further embodiment, the second cleaning fluid is mixed with a carrier gas before being mixed with the first cleaning fluid. Nitrogen, for example, can be used as a carrier gas, in particular due to its inertness. In this way, the second cleaning fluid can be conveyed safely and in the desired quantity and concentration to the inner hollow body surface.

A further developed embodiment can be characterized in that the cleaning device comprises a second dispensing unit by which the first cleaning fluid and the second cleaning fluid can be dispensed for cleaning the outer hollow body surface, and the device comprises a second drainage channel, by which the first cleaning fluid dispensed by the second dispensing unit can be drained.

The method may comprise the following steps: dispensing the first cleaning fluid for cleaning the outer hollow body surface by the second dispensing unit, draining the first cleaning fluid by the first drainage channel and/or the second drainage channel, dispensing the second cleaning fluid for cleaning the outer hollow body surface by the second dispensing unit and draining the second cleaning fluid by the first drainage channel and/or the second drainage channel.

It is true that cleaning the outer hollow body surface, which is usually more contaminated than the inner hollow body surface, is of less importance for the number of defective semiconductor wafers, since contamination originating from the outer hollow body surface cannot reach the semiconductor wafers arranged inside the hollow body as long as the hollow body is sealed with the cover. Nevertheless, a well-cleaned outer hollow body surface can also contribute to reducing the number of defective semiconductor wafers. The technical effects that can be achieved by using the first cleaning fluid and the second cleaning fluid on the outer hollow body surface correspond to those described for cleaning the inner hollow body surface.

In accordance with a further developed embodiment, the first cleaning fluid dispensed by the first dispensing unit and the mixture dispensed by the first dispensing unit are exclusively drained through the first drainage channel, and the first cleaning fluid dispensed by the second dispensing unit and the mixture dispensed by the second dispensing unit are exclusively drained through the second drainage channel.

In this embodiment, the device is constructed in such a way that a strict separation of the first cleaning fluid and second cleaning fluid used for cleaning the inner hollow body surface on the one hand and the first cleaning fluid and second cleaning fluid used for cleaning the outer hollow body surface on the other hand can be implemented. As a result, the first cleaning fluid and the second cleaning fluid used for cleaning the inner hollow body surface and the resulting mixture, respectively, are not contaminated with the particles and AMC originating from the outer hollow body surface, whereby the inner hollow body surface is effectively cleaned. The time required to clean the inner hollow body surface can be significantly reduced compared to devices known from the prior art. In addition, the amount of the first cleaning fluid required to clean the inner hollow body surface is also reduced.

It should also be emphasized that the first cleaning fluid and the second cleaning fluid, which are used for cleaning the inner hollow body surface, are discharged through the first drainage channel and the first cleaning fluid and the second cleaning fluid, which are used for cleaning the outer hollow body surface, are discharged through the second drainage channel without mixing, at least within the device. Since, as mentioned, the inner hollow body surface is usually less contaminated than the outer hollow body surface, the first cleaning fluid and the second cleaning fluid used for cleaning the inner hollow body surface are less heavily loaded with particles and AMC after cleaning than the first and second cleaning fluids used for cleaning the outer hollow body surface. It is therefore possible to also use the first cleaning fluid and the second cleaning fluid to clean the outer hollow body surface after cleaning the inner hollow body surface. The volume of the cleaning fluid used can be reduced as a result.

In a further embodiment the hollow body comprises a cover having an inner cover surface and an outer cover surface by which the opening is closable, and the device comprises a cleaning opening which is at least partially closable with a closure body, wherein the closure body comprises a reception unit for receiving the cover of the hollow body, and the cleaning device comprises a further first dispending unit by which the first cleaning fluid and the second cleaning fluid can be applied to the inner cover surface for cleaning, when the cleaning opening is closed by the closure body or the cover.

It may be appropriate that the method comprises the following steps: moving the closure body into the open position, depositing the cover on the reception unit of the closure body using the outer cover surface and releasably fastening the cover on the closure body, moving the closure body into the closure position, and dispensing the first cleaning fluid and the second cleaning fluid for cleaning the inner cover surface using the further first dispensing unit.

The embodiments of the method described so far relate to the cleaning of the inner hollow body surface and the outer hollow body surface. As mentioned, the FOUPs are closed with a removable cover. However, particles and AMC can accumulate on the inner cover surface, just as they do on the inner hollow body surface in particular, which can have a negative impact on the manufacture of the semiconductor wafers. In this embodiment, however, the device comprises a further first dispensing unit with which the inner cover surface can be cleaned. The same first cleaning fluid and the second cleaning fluid that are also used to clean the inner hollow body surface are preferably used for this purpose. However, a different first cleaning fluid and a different second cleaning fluid can also be used if this appears necessary and as long as the conditions described at the beginning regarding the properties of the first cleaning fluid and the second cleaning fluid are fulfilled.

The particles and AMC on the inner cover surface can therefore also be removed. In order to prevent the uncontrolled escape of the first cleaning fluid and the second cleaning fluid from the cleaning opening, the cleaning opening must be sealed during the cleaning process. For this purpose, either the cover or the closure body interacts with the further wall section in such a way that the cleaning opening is sealed tightly. The cleaning opening can be arranged in such a way that no particles and AMC from the surroundings of the hollow body can get into the first cleaning fluid and the second cleaning fluid during the cleaning process. It is advisable to discharge the first cleaning fluid and the second cleaning fluid via the first drainage channel. In this case, the receiving unit of the closure body interacts with the outer cover surface so that the inner cover surface is accessible without obstruction, particularly for the first cleaning fluid and the second cleaning fluid.

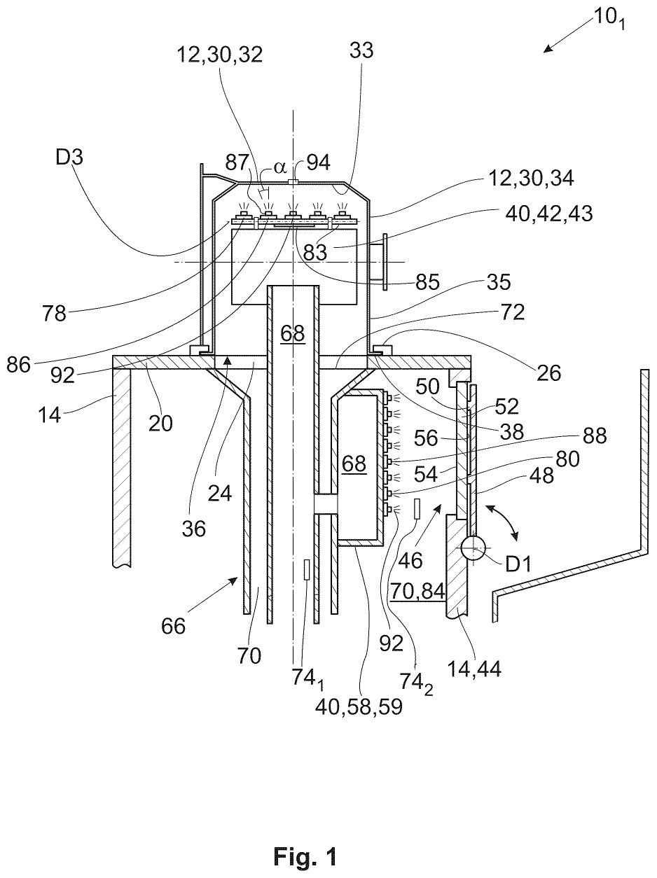

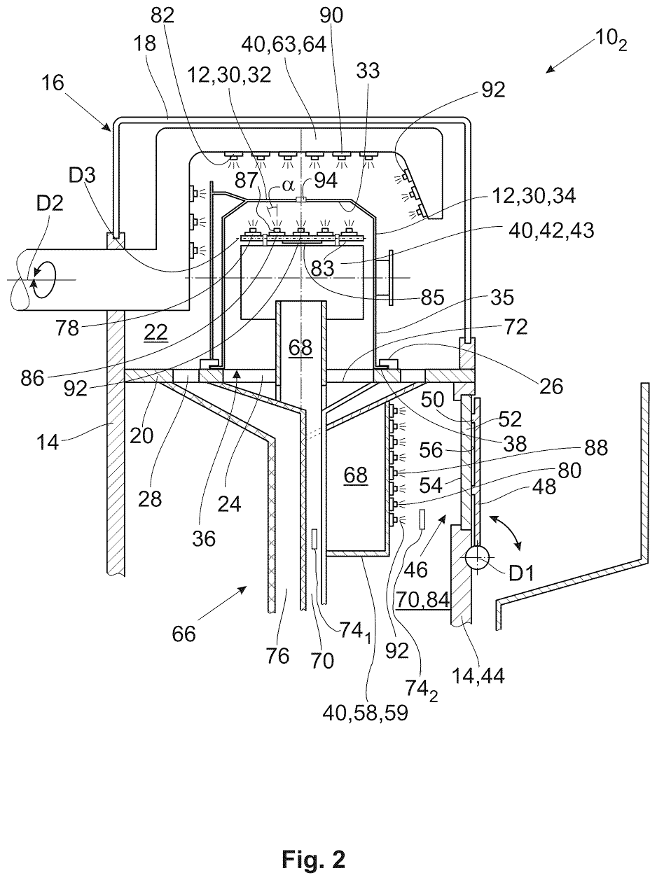

An exemplary embodiment of the invention will be explained in more detail in the following with reference to the enclosed drawings. There are shown FIG. 1 that depicts a schematic sectional view of a first embodiment of a device for cleaning pot-shaped hollow bodies, in particular transport containers for semiconductor wafers or for EUV lithography masks, and FIG. 2 depicts a principle sectional view of a second embodiment of a device for cleaning pot-shaped hollow bodies.

An embodiment of a device 10₁ according to the proposal for cleaning pot-shaped hollow bodies 12 is shown with reference to a basic sectional representation in FIG. 1. The device 10₁ has a housing 14 that forms a support wall 20. The support wall 20 forms a passage opening 24, with a locking device 26 being arranged radially outside the passage opening 24.

With a removed covering 18, a hollow body 12, in particular a transport container 30 for semiconductor wafers, also called a FOUP, or a transport container 30 for lithography masks, can be introduced into the process space 22. The hollow body 12 has a base wall 32 and, in this case, four side walls 34 so that the pot-shaped hollow body 12 is substantially parallelepiped-shaped. It is, however, by all means possible to provide the pot-shaped hollow body with a different geometry, for example a cylindrical geometry. The base wall 32 and the four side walls 34 form an inner hollow body surface 33 and an outer hollow body surface 35.

The hollow body 12 has an opening 36 that is arranged disposed opposite the base wall 32 and that is surrounded by a marginal surface 38 that is formed by the side walls 34. The hollow body 12 is designed in the manner of a flange in the region of the marginal surface 38 in the embodiment shown. The marginal surface 38 of the hollow body 12 can be placed onto the support wall 20. The passage opening 24 of the support wall 20 and the opening 36 of the hollow body 12 are at least approximately of the same size and of the same geometrical shape in the embodiment shown.

The locking device 26 is furthermore configured such that the passage opening 24 is at least approximately flush with the section of the inner hollow body surface 33 adjoining the passage opening 24.

The device 10₁ is furthermore equipped with a cleaning device 40 that has first dispensing unit 43 embodied as a first cleaning head 42, wherein the first cleaning head 42 projects over the passage opening 24, and that is thus arranged within the process space 22. When the hollow body 12 is connected to the support wall 20, the first cleaning head 42 is surrounded by the hollow body 12.

The housing 14 further comprises a wall section 44 in which a cleaning opening 46 is arranged. The wall section 44 is located at the side of the support wall 20 remote from the locking device 26. The cleaning opening 46 is at least partially closable by a closure body 48 that is rotatably fastened to the wall section 44 about a first rotational axis D1 by a drive unit, not shown. The closure body 48 can be moved between an open position in which the closure body 48 releases the cleaning opening 46 and a closure position in which the closure body 48 at least partially closes the cleaning opening 46. The closure body 48 is in the closure position in FIG. 1.

The closure body 48 has a reception unit 50 by which a cover 52 by which the hollow body 12 is closable can be releasably fastened to the closure body 48. The cover 52 forms an inner cover surface 54 and an outer cover surface 56. The inner cover surface 54 is here that side of the cover 52 that directly adjoins the inner hollow body surface 33 when the hollow body 12 has been closed by the cover 52. In other words, the inner cover surface 54 in this case faces toward the base wall 32 of the hollow body 12.

The reception unit 50 is designed in the embodiment shown such that it only interacts with the cover 52 by means of the outer cover surface 56.

The cleaning device 40 is additionally equipped with a further first dispensing unit 59 embodied as a further first cleaning head 58, wherein the further first cleaning head 58 that is arranged in the vicinity of the closure body 48 when it is in the closure position.

In the embodiment shown, the first cleaning head 42 is not movable; however, it can also be designed as rotationally and/or translationally movable.

The device 10₁ is further provided with a fluid conducting unit 66 having a first supply channel 68. The first cleaning fluid and the second cleaning fluid can be guided to the first cleaning head 42 and to the further first cleaning head 58 by means of a first supply channel 68.

The first cleaning fluid has a first surface tension, the second cleaning fluid being selected so that it is miscible with the first cleaning fluid. Furthermore, the first cleaning fluid and the second cleaning fluid are selected such that the mixture of the first cleaning fluid and the second cleaning fluid has a mixture surface tension which is lower than the first surface tension of the first cleaning fluid.

Furthermore, the fluid conducting unit 66 comprises a first drainage channel 70, with which the first cleaning fluid and second cleaning fluid or the resulting mixture dispensed from the first cleaning head 42 and from further first cleaning head 58 can be discharged again. The first drainage channel 70 has a first end 72 which is in fluid communication with the passage opening 24. As can be seen from FIG. 1, the first drainage channel 70 widens towards the first end 72 in the shape of a funnel and is connected to the support wall 20 in such a way that the first end 72 of the first drainage channel 70 is flush with the passage opening 24. The first drainage channel 70 surrounds the first supply channel 68 in an annular shape.

For discharging the first cleaning fluid and the second cleaning fluid, which are used for cleaning the inner cover surface 54, the first drainage channel 70 has a secondary channel 84, which opens into the first drainage channel 70 in a manner not shown in detail.

A first particle measuring device 74₁ is arranged in the first drainage channel 70, with which the particles which are present in the first cleaning fluid and in the second cleaning fluid which were used to clean the inner hollow body surface 33 can be determined and, in particular, counted. In addition, a second particle measuring device 74₂ is arranged in the secondary channel 84, with which the particles that are present in the first cleaning fluid and in the second cleaning fluid, which were used to clean the inner cover surface 54, can be determined and, in particular, counted.

In FIG. 2, a second embodiment of the device 10₂ is also shown by means of a principle sectional view. The basic structure of the device according to the second embodiment largely corresponds to the device 10₁ according to the first embodiment, which is why only the essential differences will be discussed below.

In the second embodiment of the device 10₂, the housing 14 forms a housing opening 16, which can be closed by a covering 18 that can be removed from the housing 14. When the housing opening 16 is closed, a process space 22 is created, which is delimited by the support wall 20, by the housing 14 itself and by the covering 18. Radially outside the locking device 26, two passage bores 28 are provided in the support wall 20 in the second embodiment example of the device 10₂, which open into the process space 22.

The cleaning device 40 moreover comprises a second dispensing unit 63 having a second cleaning head 64 that is substantially formed in U shape and is at least partially arranged in the process space 22. Unlike the first cleaning head 42, however, the second cleaning head 64 is arranged outside the hollow body 12 when the hollow body 12 is connected to the support wall 20. The second cleaning head 64 is rotatable about a second rotational axis D2, with the drive device used for this purpose not being shown. An embodiment is furthermore not shown in which the second cleaning head 64 is not only rotationally movable, but also translationally or only translationally. In the embodiment shown, the first cleaning head 42 is not movable; however, it can also be designed as rotationally and/or translationally movable.

A detailed representation of a second supply channel for supplying the first cleaning fluid and the second cleaning fluid to the second cleaning head 64 has been dispensed with for illustration reasons, but its design should be easily deducible for the skilled person.

The fluid conducting unit 66 furthermore has a second drainage channel 76 that is designed substantially exactly the same as the first drainage channel 70; however, with the two passage bores 28 being in fluid communication. In this respect, the first drainage channel 70 forms the radially inner wall of the second drainage channel 76 so that the fluid conducting unit 66 can have a very compact design. An embodiment is not shown in which a further particle measuring device 74 is arranged in the second drainage channel 76. It must be pointed out at this point that the fluid conducting unit 66 is only shown in principle in FIG. 2. The representation of the fluid conducting unit 66 in accordance with FIG. 2 does not make any claims of correctness due to the large number of channels arranged nested and at different levels. The skilled person will, however, be able to at least deduce a functional design of the fluid conducting unit 66 without problem from FIG. 1.

It follows from the above that the device 10₂ according to the second embodiment is essentially an extension of the device according to the first embodiment of the device 10₁. In the following, the mode of operation of the device 10₂ according to the second embodiment is described, from which the mode of operation of the device 10₁ according to the first embodiment example also results.

In the starting state, not shown here, the covering 18 is open and the second cleaning head 64 is rotated by 90° with respect to FIG. 2 so that the U-shaped section of the second cleaning head 64 is perpendicular to the plane of FIG. 2. The closure body 48 is in the open position in which the closure body 48 is aligned approximately horizontally with respect to FIG. 2.

The cover 52 is separated from the hollow body 12 and placed onto the reception unit 50 by a handling device, not shown, for example by a robot gripper. The open hollow body 12 is deposited on the support wall 20 using the marginal surface 38, as is shown in FIG. 1 and in FIG. 2. The hollow body 12 is subsequently locked by the locking unit 26 so that it is connected to the support wall 20 and is thus fixed. In this respect, the locking device 26 is equipped with sealing agents, not shown here, so that the hollow body 12 is sealed with respect to the support wall 20. The housing opening is now closed by the covering 18. In addition, the reception unit 50 of the closure body 48 is activated so that the cover 52 is fixed to the closure body 48. The closure body 48 is rotated by 90° into the closure position, as is shown in FIGS. 1 and 2. The cover 52 here seals the cleaning opening 46.

A first cleaning fluid is now conducted over the first supply channel 68 to the first cleaning head 42 and is dispensed by first cleaning nozzles 78 such that the inner hollow body surface 33 is cleaned by the first cleaning fluid. The further first cleaning head 58 has further first cleaning nozzles 80 by which the first cleaning fluid is applied to the inner cover surface 54 that is consequently cleaned.

The first cleaning fluid that has been dispensed by the first cleaning head 42 and has been applied to the inner hollow body surface 33 is supplied via the first drainage channel 70. The same also applies to the first cleaning fluid that has been dispensed by the further first cleaning head 58 and has been applied to the inner cover surface 54.

At the same time, the first cleaning fluid is conducted via the second supply channel, not shown here, to the second cleaning head 64 where the first cleaning fluid is dispensed by second cleaning nozzles 82 to clean the outer hollow body surface 35. In this respect, the second cleaning head 64 can be rotated about the second rotational axis D2. The first cleaning fluid, which has been dispensed by the second cleaning head 64 and applied to the outer hollow body surface 35, is discharged via the second drainage channel 76.

The first cleaning nozzles 78 and the further first cleaning nozzles 80, and the second cleaning nozzles 82 can be configured such that the spray angle α at which the first cleaning fluid are dispensed is settable. For this purpose, the first cleaning nozzles 78, the further first cleaning nozzles 80, and the second cleaning nozzles 82 can be supported in spherical head shape. Alternatively or accumulatively, in particular the first cleaning nozzles 78 can be arranged on a tubular body 83 rotatable about a third rotational axis D3 so that the spray angle α can be set. The first cleaning head 42 at least comprises a setting device 85 by which the spray angle α can be set. The further first cleaning nozzles 80 and the second cleaning nozzles 82 can be correspondingly formed, with the spray angle α at which the first cleaning fluid is dispensed by the further first cleaning nozzles 80 is likewise set by the setting device 85. The setting device 85 can also be configured such that the spray angle α of the second cleaning nozzles 80 located on the second cleaning head 64 can likewise be set. It can hereby be achieved that the first cleaning fluid impinge perpendicular or almost perpendicular on the inner hollow body surface 33 and on the inner cover surface or the outer hollow body surface 35.

Furthermore, at least one coupling unit 87 for coupling sound waves into the first cleaning fluid is provided. In the embodiment shown, some of the coupling units 87 are integrated in at least some of the first cleaning nozzles 78 and are designed as so-called “megasonic nozzles”. A megasonic wave can be coupled into the first cleaning fluid dispensed by the first cleaning nozzles 78. The same can correspondingly be provided for the further first nozzles 80 and the second cleaning nozzles 82.

The first cleaning nozzles 78 can be opened and closed independently of one another. It is consequently possible to clean different sections of the inner hollow body surface 33 first and other sections later. For example, sections that are less soiled according to experience can be cleaned first and sections that are more soiled according to experience can be subsequently cleaned. The further first cleaning nozzles 80 and the second cleaning nozzles 82 can be designed correspondingly such that the inner cover surface 54 and the outer hollow body surface 35 can be correspondingly cleaned.

Particles and AMC that were located on the inner hollow body surface 33 and on the inner cover surface 54 are removed by the first cleaning fluid. The particles that originate from the inner hollow body surface 33 are detected by the first particle measuring device 74₁ and the particles that originate from the inner cover surface 54 are detected by the second particle measuring device 74₂. In this respect, the first particle measuring device 74₁ and the second particle measuring device 74₂ are configured such that the number of particles that pass through the particle measuring device 74 at a given volume flow within a certain time is determined. It can hereby be determined whether the inner hollow body surface 33 and the inner cover surface 54 have been cleaned to the desired degree or not. If, for example, the inner hollow body surface 33 is sufficiently clean, the cleaning process for the hollow body 12 can be aborted while the cleaning process for the inner cover surface 54 is continued. In the meantime, the hollow body 12 can be removed from the device 10₂ by the robot gripper, whereby time can be saved.

An embodiment is not shown in which the particle measuring device 74 is arranged downstream of the opening of the secondary channel 84 into the first drainage channel 70. In this case, no distinction can be made whether the particles have originated from the inner cover surface 54 or from the inner hollow body surface 33. The cleaning process can nevertheless be aborted when the number of particles falls below a certain degree.

The cleaning of the inner hollow body surface 33 and of the inner cover surface 54 generally has a greater importance than the cleaning of the outer hollow body surface 35. If it is found that the inner hollow body surface 33 and the inner cover surface 54 have been cleaned to the desired degree, the cleaning process can be aborted independently of the degree to which the outer hollow body surface 35 has been treated.

After the first cleaning fluid has been applied both to the inner hollow body surface 33 and to the outer hollow body surface 35 as well as to the inner cover surface 54, the first cleaning fluid is removed from the hollow body 12 in the manner described. It should be noted that, depending on the first cleaning fluid used, residues may remain in the hollow body 12. The second cleaning fluid is now applied to the outer hollow body surface 35, the inner hollow body surface 33 and the inner cover surface 54, essentially in the same way as the first cleaning fluid is applied. The second cleaning fluid can be mixed with a carrier gas, for which purpose a mixing device not shown here can be used. The carrier gas can be nitrogen, for example.

Due to the described properties of the first cleaning fluid and the second cleaning fluid with regard to miscibility and surface tension, the resulting mixture, which consists of the residues of the first cleaning fluid and the second cleaning fluid, can be removed from the hollow body 12 largely residue-free, without leaving behind locally concentrated impurities. In this respect, the cleaning process can be interrupted at this point.

The first cleaning fluid and the second cleaning fluid, which have been dispensed by the second cleaning head 64 and applied to the outer hollow body surface 35, or the resulting mixture, are discharged through the second drainage channel 76. Consequently, the first cleaning fluid and the second cleaning fluid or the resulting mixture, which have been used for cleaning the outer hollow body surface 35, are discharged separately from those which have been used for cleaning the inner hollow body surface 33. As a result, particles and AMC originating from the outer hollow body surface 35 cannot reach the inner hollow body surface 33 or the inner cover surface 54.

Purely optionally, a first drying gas and a second drying gas, for example air or nitrogen, can be fed to the first cleaning head 42, to the further first cleaning head 58 and to the second cleaning head 64 via the first supply channel 68 or the second supply channel not shown in substantially the same way as the first and second cleaning fluids. The first cleaning head 42 has first drying nozzles 86, the further first cleaning head 58 has further first drying nozzles 88 and the second cleaning head 64 has second drying nozzles 90, with which the first drying gas or the second drying gas can be emitted and applied to the inner hollow body surface 33, the inner cover surface 54 and the outer hollow body surface 35. The first drying gas and the second drying gas displace the first cleaning fluid and the second cleaning fluid or the resulting mixture from the device 10₂. Residues of the first and second cleaning fluids can also be blown away.

The first cleaning head 42, the further first cleaning head 58, and the second cleaning head can furthermore each be heated via infrared diodes 92 by which residues of the first and second cleaning fluids can be heated and vaporized, as a result of which they can be removed from the device 10₂ by the first and second drying gases.

After the termination of the drying process, the covering 18 is opened and the closure body 48 is moved into the open position. The cleaned hollow body 12 is removed from the process space. The reception unit 50 is deactivated, as a result, the cover 52 can be removed from the closure body 48 and supplied to the hollow body 12 for the closing thereof.

The hollow body 12 can now be placed in a vacuum chamber (not shown), for which purpose the cover 52 is again separated from the hollow body 12. There, a vacuum is applied to the hollow body 12 and, in particular, to the inner hollow body surface 33, the inner cover surface 54 and the outer hollow body surface 35, so that residues of the mixture of the first cleaning fluid and the second cleaning fluid can be vaporized.

A further hollow body 12 to be cleaned can now be handled in the described manner in the device 10₂.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below. All numerical values are “about” or “approximately” the indicated value, meaning the values take into account experimental error, machine tolerances and other variations that would be expected by a person having ordinary skill in the art.

The foregoing has outlined features of several embodiments so that those skilled in the art can better understand the present disclosure. Those skilled in the art should appreciate that they can readily use the present disclosure as a basis for designing or modifying other methods or devices for carrying out the same purposes and/or achieving the same advantages of the embodiments disclosed herein. Those skilled in the art should also realize that such equivalent constructions do not depart from the spirit and scope of the present disclosure, and that they can make various changes, substitutions, and alterations herein without departing from the spirit and scope of the present disclosure, and the scope thereof is determined by the claims that follow.

To the extent a term used in a claim is not defined above, it should be given the broadest definition persons in the pertinent art have given that term as reflected in at least one printed publication or issued patent. Furthermore, all patents, test procedures, and other documents cited in this application are fully incorporated by reference to the extent such disclosure is not inconsistent with this application and for all jurisdictions in which such incorporation is permitted.

### REFERENCE LIST

10₁ device
10₂ device
12 hollow body
14 housing
16 housing opening
18 covering
20 support wall
22 process space
24 passage opening
26 locking device
28 passage bore
30 transport container
32 base wall
33 inner hollow body surface
34 side wall
35 outer hollow body surface
36 opening
38 marginal surface
40 cleaning device
42 first cleaning head
43 first dispensing unit
44 wall section
46 cleaning opening
48 closure body
50 reception unit
52 cover
54 inner cover surface
56 outer cover surface
58 further first cleaning head
59 further first dispensing unit
63 second dispensing unit
64 second cleaning head
66 fluid conducting unit
68 first supply channel
70 first drainage channel
72 first end
74 particle measuring device
74₁, 74₂ particle measuring device
76 second drainage channel
78 first cleaning nozzle
80 further first cleaning nozzle
82 second cleaning nozzles
83 tubular body
84 secondary channel
85 setting device
86 first drying nozzles
87 coupling unit
88 further first drying nozzles
90 second drying nozzles
92 infrared diodes
α spray angle
D1 first rotational axis
D2 second rotational axis
D3 third rotational axis

1.-8. (canceled)

9. A method for cleaning pot-shaped hollow bodies for semiconductor wafers or for lithography masks, comprising:
providing a hollow body to be cleaned, the hollow body comprising one or more side walls that define an inner hollow body surface and an opening that is enclosed by the side wall, and
providing a cleaning device with a first dispensing unit by which a first cleaning fluid and a second cleaning fluid for cleaning the inner hollow body surface can be dispensed, and a first drainage channel through which the first cleaning fluid and the second cleaning fluid dispensed by the cleaning device can be drained;
dispensing of the first cleaning fluid for cleaning the inner hollow body surface by the first dispensing unit;
draining the first cleaning fluid by the first drainage channel, wherein the first cleaning fluid has a first surface tension;
dispensing of the second cleaning fluid for cleaning the inner hollow body surface by the first dispensing unit, wherein the second cleaning fluid is miscible with the first cleaning fluid and the mixture so generated by the first cleaning fluid and the second cleaning fluid has a mixture surface tension that is lower than the first surface tension; and
draining the mixture through the first drainage channel or through a further drainage channel.

10. The method of claim 9, wherein the second cleaning fluid is applied to the inner hollow surface body in the vapor state.

11. The method of claim 9, wherein water is used as the first cleaning fluid and an organic solvent is used as the second cleaning fluid.

12. The method of claim 11, wherein the organic solvent has a water solubility of at least 1 g/L and a vapor pressure of between 25 Pa and 25000 Pa.

13. The method of claim 10, wherein the second cleaning fluid is mixed with a carrier gas before being mixed with the first cleaning fluid.

14. The method of claim 8, wherein:
the cleaning device comprises a second dispensing unit by which the first cleaning fluid and the second cleaning fluid can be dispensed for cleaning the outer hollow body surface, and
the device comprises a second drainage channel by which the first cleaning fluid dispensed by the second dispensing unit is drained, and
the method further comprises dispensing the first cleaning fluid for cleaning the outer hollow body surface by the second dispensing unit; draining the first cleaning fluid by the first drainage channel and/or the second drainage channel; dispensing the second cleaning fluid for cleaning the outer hollow body surface by the second dispensing unit; and draining the second cleaning fluid by the first drainage channel and/or the second drainage channel.

15. The method of claim 14, wherein the first cleaning fluid dispensed by the first dispensing unit and the mixture dispensed by the first dispensing unit are exclusively drained through the first drainage channel, and wherein the first cleaning fluid dispensed by the second dispensing unit and the mixture dispensed by the second dispensing unit are exclusively drained through the second drainage channel.

16. The method of claim 14, wherein the hollow body comprises a cover having an inner cover surface and an outer cover surface by which the opening is closable, and the device further comprises a cleaning opening, which is at least partially closable with a closure body, wherein the closure body comprises a reception unit for receiving the cover of the hollow body, and the cleaning device further comprises a further first dispensing unit by which the first cleaning fluid and the second cleaning fluid can be applied to the inner cover surface for cleaning, when the cleaning opening is closed by the closure body or the cover, and the method further comprises: moving the closure body into the open position, depositing the cover on the reception unit of the closure body using the outer cover surface and releasably fastening the cover on the closure body, moving the closure body into the closure position, and dispensing the first cleaning fluid and the second cleaning fluid for cleaning the inner cover surface using the further first dispensing unit.
